(19) United States
(12) Patent Application Publication
(10) Pub. No.: US 2010/0244251 A1
(43) Pub. Date: Sep. 30, 2010

(54) SEMICONDUCTOR DEVICE AND METHOD FOR FABRICATING THE SAME

(75) Inventors: Naoki TORAZAWA, Toyama (JP); Toru Hinomura, Osaka (JP)

Correspondence Address: MCDERMOTT WILL & EMERY LLP, 600 13TH STREET, NW, WASHINGTON, DC, 20005-3096, US

(73) Assignee: Panasonic Corporation, Osaka (JP)

(21) Appl. No.: 12/813,024

(22) Filed: Jun. 10, 2010

Related U.S. Application Data
(63) Continuation of application No. PCT/JP2008/003246, filed on Jul. 10, 2009.

(30) Foreign Application Priority Data
Sep. 29, 2008 (JP) 2008-250805

(51) Int. Cl. H01L 23/538; H01L 21/768

(52) U.S. Cl. 257/741; 438/109; 257/777; 257/774; 257/E21.575; 257/E23.169

(57) ABSTRACT

A semiconductor device includes a first semiconductor chip, an electrode pad formed in an upper surface portion of the first semiconductor chip, a second semiconductor chip formed on the first semiconductor chip, and a through-via formed in the second semiconductor chip. A hollowed portion is formed in the electrode pad, and a bottom portion of the through-via is embedded in the hollowed portion.

### CROSS-REFERENCE TO RELATED APPLICATIONS

This is a continuation of PCT International Application PCT/JP2009/003246 filed on Jul. 10, 2009, which claims priority to Japanese Patent Application No. 2008-250805 filed on Sep. 29, 2008. The disclosures of these applications including the specifications, the drawings, and the claims are hereby incorporated by reference in their entirety.

### BACKGROUND

The present disclosure relates to semiconductor devices having a three-dimensional interconnection structure, and methods for fabricating the semiconductor devices.

In recent years, there has been a demand for smaller-size and higher-performance semiconductor elements in order to provide smaller-size and higher-performance electronic apparatuses, such as, representatively, computers and communication apparatuses. To meet the demand, methods of connecting semiconductor elements in a three-dimensional manner have been proposed in order to decrease the size and increase the density.

As an example of conventional semiconductor device fabricating methods, one described in Japanese Patent No. 3895987 will be described hereinafter with reference to FIGS. 10A-10F. FIGS. 10A-10F are cross-sectional views showing steps of the semiconductor device fabricating method of Japanese Patent No. 3895987.

Initially, as shown in FIG. 10A, an insulating film 11 is formed on an upper surface of a substrate 10 made of Si, trenches 13c and 13d are then formed in the substrate 10 and the insulating film 11, and metal plugs 15c and 15d are then formed in the trenches 13c and 13d, respectively, with an insulating film 14 being interposed between the metal plugs 15c and 15d and wall surfaces of the trenches 13c and 13d, respectively.

Next, as shown in FIG. 10B, a multilayer interconnect layer 16 is formed on the substrate 10, and a pad 17 is then formed in an upper surface portion of the multilayer interconnect layer 16.

Next, as shown in FIG. 10C, the substrate 10 is thinned from a lower surface thereof so that bottom portions of the metal plugs 15c and 15d protrude.

Next, as shown in FIG. 10D, an insulating film 18 is formed to cover the metal plugs 15c and 15d exposed from the lower surface of the substrate 10.

Next, as shown in FIG. 10E, the insulating film 18 is polished by chemical mechanical polishing (CMP) so that the metal plugs 15c and 15d are exposed. As a result, the fabrication of a chip is completed.

Thereafter, as shown in FIG. 10F, chips 1-3 which are formed in the aforementioned manner are stacked one on top of another with the pad 17 and the metal plug 15 being joined with a solder bump 19 formed on the pad 17, thereby completing the fabrication of a semiconductor device.

### SUMMARY

However, the following problem occurs in the semiconductor device fabricated by the aforementioned conventional fabrication method. Specifically, because the pad 17 and the metal plug 15 are joined with the solder bump 19, the semiconductor device having the multi-chip stacked arrangement has a low mechanical strength against lateral force. Moreover, in the step of FIG. 10E, the lower surface of the metal plug 15 is polished by CMP, resulting in a smooth and even surface, and therefore, the contact area between the metal plug 15 and the solder bump 19 is small, whereby the bond strength between the pad 17 and the metal plug 15 is further reduced.

In view of the foregoing, the detailed description describes implementations of a semiconductor device having a three-dimensional interconnection structure whose mechanical strength is increased by increasing the bond strength between a through-via and an electrode pad.

To achieve the object, an example semiconductor device includes a first semiconductor chip, an electrode pad formed in an upper surface portion of the first semiconductor chip, a second semiconductor chip formed on the first semiconductor chip, and a through-via formed in the second semiconductor chip. A hollowed portion is formed in the electrode pad, and a bottom portion of the through-via is embedded in the hollowed portion.

In the example semiconductor device, the hollowed portion may have a depth of 2 nm or more.

In the example semiconductor device, the hollowed portion may have a depth of 10 nm or more.

In the example semiconductor device, a maximum diameter of the hollowed portion may be greater than a diameter of the through-via at an upper surface of the electrode pad.

In the example semiconductor device, an upper surface of the electrode pad may be lower than an upper surface of the first semiconductor chip.

In the example semiconductor device, the electrode pad and the through-via may directly contact each other without a bump interposed therebetween.

In the example semiconductor device, an adhesive layer may be formed between the first and second semiconductor chips.

In the example semiconductor device, the through-via may be electrically connected to an interconnect formed in the second semiconductor chip.

In the example semiconductor device, the electrode pad may be made of a material containing copper.

A first example method for fabricating a semiconductor device, includes the steps of (a) preparing a first semiconductor chip including an electrode pad in an upper surface portion thereof, and a second semiconductor chip, (b) attaching the second semiconductor chip to an upper surface of the first semiconductor chip, (c) forming a through-via hole in the second semiconductor chip, (d) after steps (b) and (c), forming a hollowed portion in the electrode pad, and (e) forming a through-via by embedding a conductive film in the through-via hole and the hollowed portion.

In the first example method, step (c) may be performed after step (b). In this case, step (d) may include forming the hollowed portion by dry etching or wet etching. The first example method may further include the step of, between steps (d) and (e), forming a barrier metal film on a wall surface of each of the through-via hole and the hollowed portion. Alternatively, step (d) may include forming a barrier metal film on a wall surface of the through-via hole and then forming the hollowed portion in the electrode pad by resputtering. The resputtering may be performed using Ar gas.

In the first example method, step (c) may be performed before step (b). In this case, step (c) may include forming the through-via hole extending to a mid-depth of the second semiconductor chip and then polishing or etching a surface of the second semiconductor chip which the through-via hole does not penetrate, until a bottom surface of the through-via hole is exposed. Also in this case, step (d) may include forming the hollowed portion by dry etching or wet etching. The first example method may further include the step of, between steps (d) and (e), forming a barrier metal film on a wall surface of each of the through-via hole and the hollowed portion. Alternatively, step (d) may include forming a barrier metal film on a wall surface of the through-via hole and then forming the hollowed portion in the electrode pad by resputtering. The resputtering may be performed using Ar gas.

In the first example method, the hollowed portion may have a depth of 2 nm or more.

In the first example method, the hollowed portion may have a depth of 10 nm or more.

In the first example method, a maximum diameter of the hollowed portion may be greater than a diameter of the through-via at an upper surface of the electrode pad.

In the first example method, an upper surface of the electrode pad may be lower than the upper surface of the first semiconductor chip.

In the first example method, the through-via may be electrically connected to an interconnect formed in the second semiconductor chip.

A second example method for fabricating a semiconductor device, includes the steps of (a) preparing a first semiconductor chip including an electrode pad in an upper surface portion thereof, and a second semiconductor chip, (b) forming a through-via in the second semiconductor chip, (c) forming a metal-containing film in a bottom portion of the through-via, and (d) attaching the second semiconductor chip to an upper surface of the first semiconductor chip, and causing the metal-containing film formed in the bottom portion of the through-via to contact the electrode pad.

In the second example method, step (b) may include forming a through-via hole extending to a mid-depth of the second semiconductor chip, the through-via hole corresponding to the through-via, then embedding a conductive film in the through-via hole to form the through-via, and then polishing or etching a surface of the second semiconductor chip which the through-via does not penetrate, until a bottom surface of the through-via is exposed.

In the second example method, step (c) may include forming the metal-containing film by electroless plating.

In the second example method, the metal-containing film may contain Cu, Ni, or Co.

In the first or second example method, the electrode pad may be made of a material containing copper.

According to the example semiconductor device and the first example method of the present disclosure, a hollowed portion is formed in the electrode pad of the first semiconductor chip, and a bottom portion of the through-via of the second semiconductor chip is disposed in the hollowed portion. Therefore, the contact area between the through-via and the electrode pad is increased, resulting in an increase in the bond strength between the through-via and the electrode pad. Moreover, by embedding the bottom portion of the through-via in the hollowed portion of the electrode pad, the mechanical strength against lateral force can be increased. Therefore, the mechanical strength of a semiconductor device having a three-dimensional interconnection structure can be increased.

Moreover, according to the first method of the present disclosure, for example, if the formation of the through-via hole, the formation of the hollowed portion, and the formation of the through-via by embedding a conductive film are continuously performed in vacuum, the through-via and the electrode pad can be joined while avoiding oxidation of the bottom surface of the through-via and the upper surface of the electrode pad, resulting in a further increase in the bond strength between the through-via and the electrode pad.

According to the second method of the present disclosure, a metal-containing film is formed in a bottom portion of the through-via, and the metal-containing film and the electrode pad contact each other. Therefore, uneven interfaces can be formed between the through-via and the metal-containing film, and between the metal-containing film and the electrode pad. As a result, the effective contact area between the through-via and the electrode pad is increased, resulting in an increase in the bond strength between the through-via and the electrode pad.

As described above, the present disclosure, which relates to semiconductor devices and methods for fabricating the semiconductor devices, increases the bond strength between the through-via and the electrode pad, thereby increasing the mechanical strength of a semiconductor device having a three-dimensional interconnection structure, and is therefore useful.

### BRIEF DESCRIPTION OF THE DRAWINGS

FIG. 1 is a cross-sectional view of a semiconductor device according to a first embodiment of the present disclosure.

FIG. 2 is a cross-sectional view of a semiconductor device according to a variation of the first embodiment of the present disclosure.

FIGS. 3A-3F are cross-sectional views showing steps of a semiconductor device fabricating method according to a second embodiment of the present disclosure.

FIG. 4 is a cross-sectional view of a step in a semiconductor device fabricating method according to a variation of the second embodiment of the present disclosure.

FIGS. 5A-5G are cross-sectional views showing steps of a semiconductor device fabricating method according to a third embodiment of the present disclosure.

FIGS. 6A-6G are cross-sectional views showing steps of a semiconductor device fabricating method according to a fourth embodiment of the present disclosure.

FIG. 7 is a cross-sectional view of a step in a semiconductor device fabricating method according to a variation of the fourth embodiment of the present disclosure.

FIGS. 8A-8H are cross-sectional views showing steps of a semiconductor device fabricating method according to a fifth embodiment of the present disclosure.

FIGS. 9A-9G are cross-sectional views showing steps of a semiconductor device fabricating method according to a sixth embodiment of the present disclosure.

FIGS. 10A-10F are cross-sectional views of steps of a conventional semiconductor device fabricating method described in Japanese Patent No. 3895987.

### DETAILED DESCRIPTION

### First Embodiment

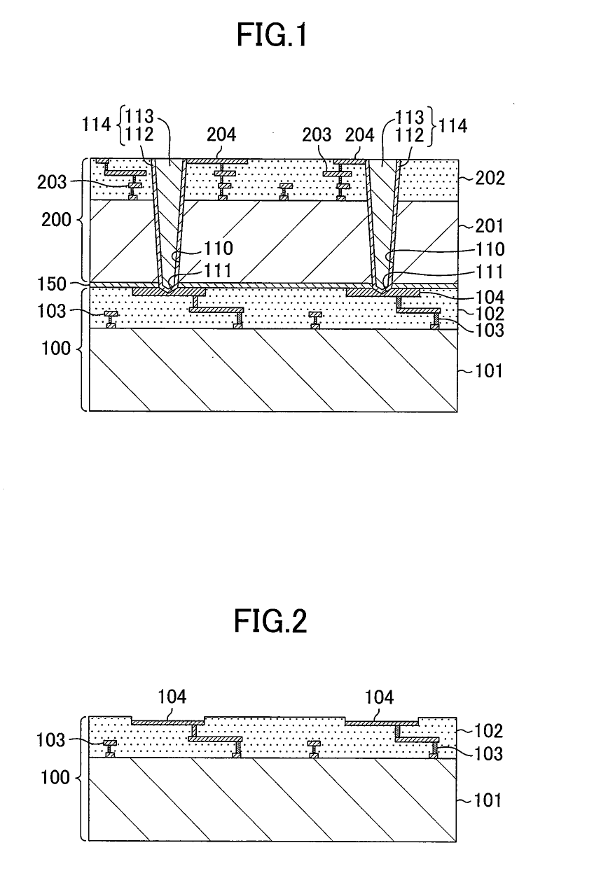

A semiconductor device according to a first embodiment of the present disclosure will be described hereinafter with reference to FIG. 1. FIG. 1 is a cross-sectional view of the semiconductor device of the first embodiment.

As shown in FIG. 1, the semiconductor device of the first embodiment includes a first semiconductor chip 100, and a second semiconductor chip 200 formed on the first semiconductor chip 100. The first and second semiconductor chips 100 and 200 are joined with an adhesive layer 150.

In the first semiconductor chip 100, a multilayer insulating film 102 including one or more insulating films is formed on a first silicon substrate 101 in which semiconductor elements (not shown) are formed. Multilayer interconnects 103 each including a contact plug, an interconnect, a via, and the like are formed in the multilayer insulating film 102. Electrode pads 104 which are joined to the multilayer interconnects 103 are formed in an uppermost portion of the multilayer insulating film 102.

In the second semiconductor chip 200, a multilayer insulating film 202 including one or more insulating films is formed on a second silicon substrate 201 in which semiconductor elements (not shown) are formed. Multilayer interconnects 203 each including a contact plug, an interconnect, a via, and the like are formed in the multilayer insulating film 202. Electrode pads 204 which are joined to the multilayer interconnects 203 are formed in an uppermost portion of the multilayer insulating film 202. Moreover, in the second semiconductor chip 200, through-vias 114 are formed which electrically connect the multilayer interconnects 203 and the electrode pads 104 of the first semiconductor chip 100. Note that, in this embodiment, the through-vias 114 are electrically connected to the multilayer interconnects 203 via the electrode pads 204.

Specifically, the through-vias 114 are formed by successively embedding a barrier metal film 112 and a Cu (copper) film 113 in through-via holes 110 penetrating through the second silicon substrate 201 and the multilayer insulating film 202. Here, a feature of this embodiment is that a hollowed portion (anchor) 111 is formed in the electrode pad 104 of the first semiconductor chip 100, and a bottom portion of the through-via 114 is embedded in the hollowed portion 111, whereby the electrode pad 104 and the through-via 114 are directly joined.

As described above, in this embodiment, the semiconductor chips 100 and 200 are joined with the adhesive layer 150, and the multilayer interconnects 103 and 203 in the semiconductor chips 100 and 200 are electrically connected via the through-vias 114, whereby the semiconductor device is formed. Although FIG. 1 shows the semiconductor device in which the two semiconductor chips 100 and 200 are stacked, needless to say a semiconductor device may be formed by stacking three or more semiconductor chips.

As described above, a feature of the semiconductor device of the first embodiment is that the bottom portion of the through-via 114 is embedded in the hollowed portion 111 formed in the electrode pad 104 of the first semiconductor chip 100 so that the electrode pad 104 and the through-via 114 directly contact each other. As a result, advantageously, the electrode pad 104 and the through-via 114 contact each other without the formation of a bump. Moreover, the overall height of the semiconductor device can be advantageously reduced by an amount corresponding to the height of the bump. Moreover, because the bottom portion of the through-via 114 is embedded in the hollowed portion 111 of the electrode pad 104, the contact area between the through-via 114 and the electrode pad 104 can be increased, resulting in an increase in the bond strength between the through-via 114 and the electrode pad 104, and an increase in the mechanical strength against lateral force. Therefore, the mechanical strength of the semiconductor device having the three-dimensional interconnection structure can be increased.

Note that, in the first embodiment, the hollowed portion 111 preferably has a depth of 2 nm or more, more preferably 10 nm or more. Here, the term “depth” with respect to the hollowed portion 111 refers to a depth from an upper surface of the electrode pad 104 to a deepest portion of the hollowed portion 111. Specifically, if the depth of the hollowed portion 111 is 2 nm or more, a sufficient mechanical strength against lateral force can be maintained. If the depth of the hollowed portion 111 is 10 nm or more, a more sufficient mechanical strength against lateral force can be maintained. Here, the electrode pad 104 may have a thickness of, for example, about 1-5 μm. The electrode pad 104 may also have an area of, for example, but not limited to, about 100 μm×100 μm.

Moreover, in the first embodiment, the hollowed portion 111 preferably has a maximum diameter greater than a diameter of the through-via 114 at the upper surface of the electrode pad 104. In this case, the contact area between the through-via 114 and the electrode pad 104 can be further increased, resulting in a further increase in the reliability of the bond between the through-via 114 and the electrode pad 104. Here, the diameter of the through-via 114 (a diameter at the upper surface of the electrode pad 104) may be, for example, about 1-10 μm. Also, the through-via 114 may have a height of, for example, but not limited to, about 50 μm.

Moreover, in the first embodiment, the multilayer interconnect 103 (including the electrode pad 104), the multilayer interconnect 203 (including the electrode pad 204), and the through-via 114 may be made of, for example, but not limited to, copper or a copper alloy.

Moreover, in the first embodiment, as shown in, for example, FIG. 2, the electrode pad 104 is preferably formed so that the upper surface of the electrode pad 104 is lower than an upper surface of the first semiconductor chip 100 (i.e., an upper surface of the multilayer insulating film 102). In this case, the mechanical strength against lateral force can be further increased.

### Second Embodiment

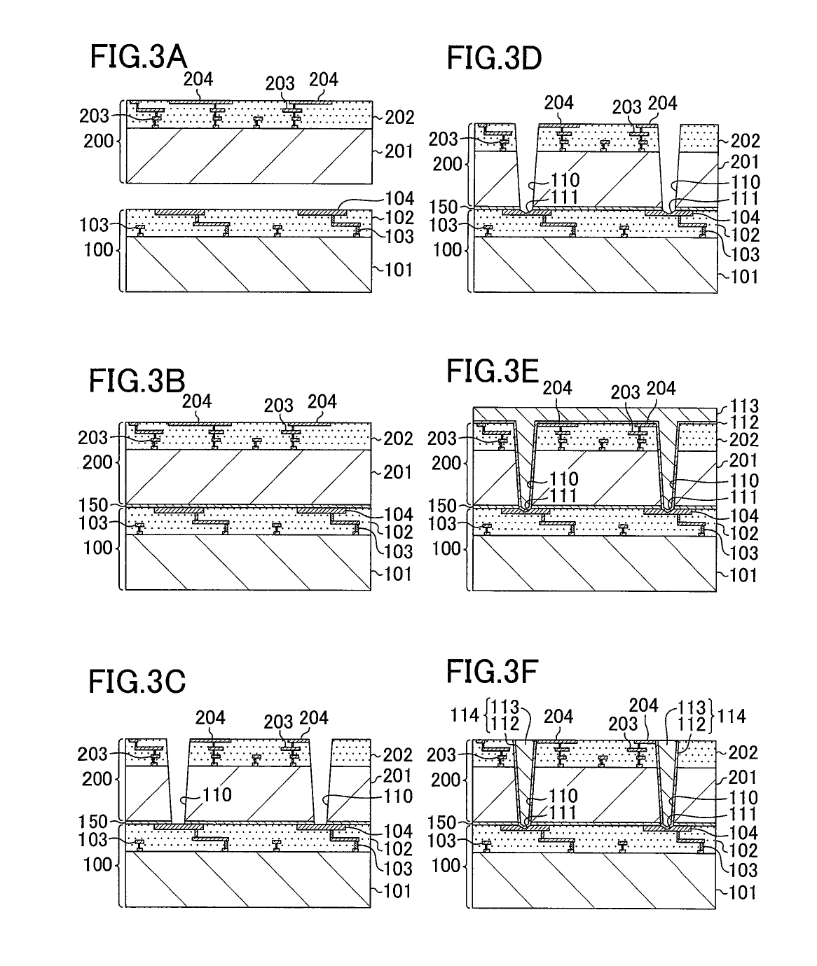

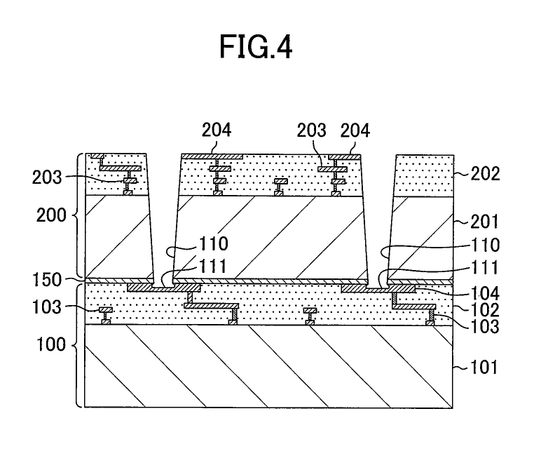

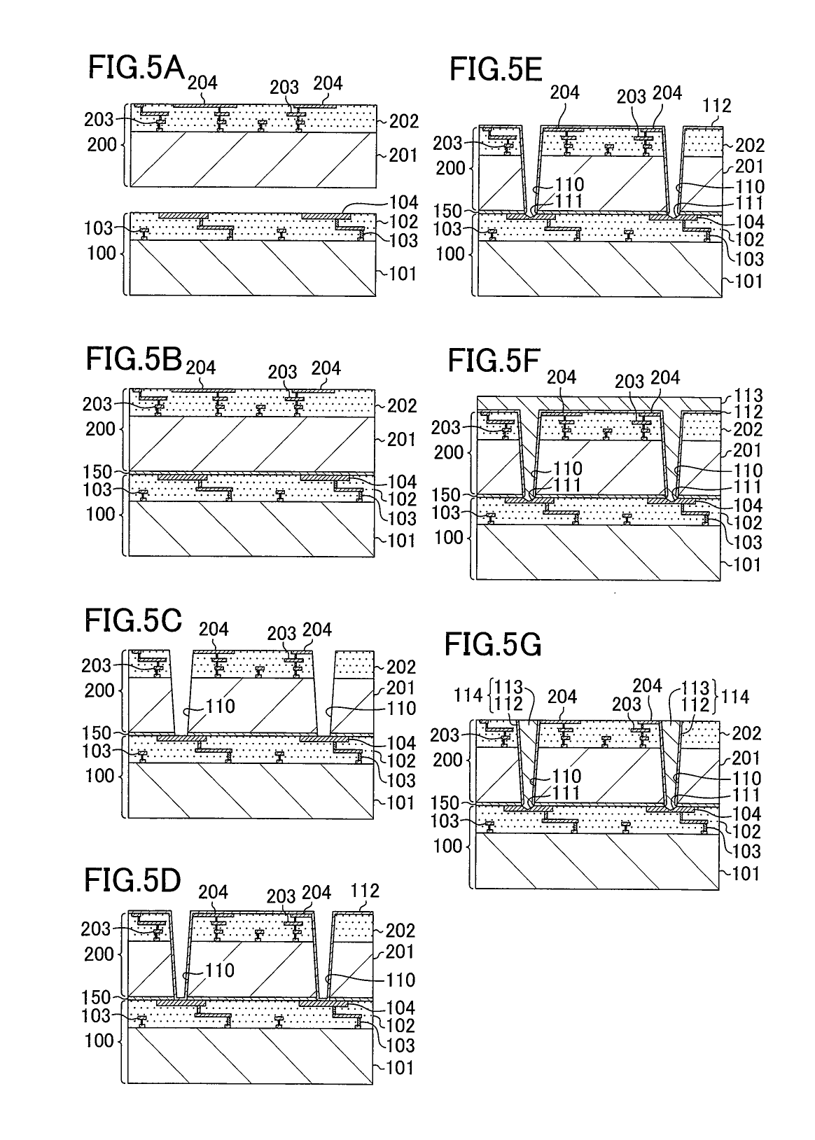

A method for fabricating a semiconductor device according to a second embodiment of the present disclosure will be described hereinafter with reference to the drawings. FIGS. 3A-3F are cross-sectional views showing steps of the semiconductor device fabricating method of the second embodiment of the present disclosure.

Initially, as shown in FIG. 3A, semiconductor elements (not shown) are formed in a first silicon substrate 101, and thereafter, although steps will not be described in detail, a multilayer insulating film 102 including one or more insulating films is formed on the first silicon substrate 101, and multilayer interconnects 103 each including a contact plug, an interconnect, a via, and the like are formed in the multilayer insulating film 102. Thereafter, electrode pads 104 are formed in an uppermost portion of the multilayer insulating film 102 so that the electrode pads 104 are connected to the multilayer interconnects 103. As a result, a first semiconductor chip 100 is formed which includes the first silicon substrate 101, the multilayer insulating film 102, the multilayer interconnects 103, the electrode pads 104, and the like. Similarly, semiconductor elements (not shown) are formed in a second silicon substrate 201, and thereafter, although steps will not be described in detail, a multilayer insulating film 202 including one or more insulating films is formed on the second silicon substrate 201, and multilayer interconnects 203 each including a contact plug, an interconnect, a via, and the like are formed in the multilayer insulating film 202. Thereafter, electrode pads 204 are formed in an uppermost portion of the multilayer insulating film 202 so that the electrode pads 204 are connected to the multilayer interconnects 203. As a result, a second semiconductor chip 200 is formed which includes the second silicon substrate 201, the multilayer insulating film 202, the multilayer interconnects 203, and the electrode pads 204, and the like.

Here, of the multilayer insulating films 102 and 202, an insulating film in which interconnects are formed is preferably a carbon-containing silicon oxide film (SiOC film) for the purpose of reducing the capacitance between the interconnects.

Moreover, the interconnects, the vias, and the like constituting the multilayer interconnects 103 and 203 are preferably made of Cu (copper) or a Cu alloy for the purpose of reducing the resistance. The interconnects, the vias, and the like are preferably formed by a dual damascene process for the purpose of simplifying the process.

Although the electrode pads 104 and 204 may be made of Cu, aluminum (Al), an alloy thereof, or the like, the electrode pads 104 and 204 are preferably made of Cu for the purpose of reducing the resistance. The electrode pads 104 and 204 may have a two-dimensional shape of, for example, but not limited to, a circle (or substantially a circle), a square (or substantially a square), a rectangle (or substantially a rectangle), or the like.

Next, as shown in FIG. 3B, the first and second semiconductor chips 100 and 200 are attached to each other with an adhesive layer 150 at a wafer level. Specifically, for example, a polybenzoxazole (PBO) resin having a thickness of about 15 μm is applied to an upper surface of the first semiconductor chip 100 to form the adhesive layer 150. Thereafter, the second semiconductor chip 200 is pressed against the first semiconductor chip 100 with the adhesive layer 150 being interposed therebetween. In this situation, for example, a thermal treatment is performed at 320° C. for 30 min to cure the adhesive layer 150. Note that the material for the adhesive layer 150 is not limited to the PBO resin, and may be a thermosetting adhesive, an ultraviolet curable adhesive, or the like.

Next, as shown in FIG. 3C, a resist pattern (not shown) having a through-via pattern is formed on the multilayer insulating film 202 of the second semiconductor chip 200 by photolithography. Thereafter, using the resist pattern as a mask, the multilayer insulating film 202, the second silicon substrate 201, and the adhesive layer 150 are successively dry etched to form through-via holes 110 penetrating the second silicon substrate 201. As a result, upper surfaces of the electrode pads 104 of the first semiconductor chip 100 are exposed in the through-via holes 110. Note that, in this embodiment, in order to reliably establish electrical contact between through-vias and the multilayer interconnects 203 in the second semiconductor chip 200, large electrode pads 204 are formed in the step of FIG. 3A, and a portion of each of the electrode pads 204 is etched in the step of FIG. 3C to form the corresponding through-via hole 110 so that the through-via hole 110 contacts the electrode pad 204.

Next, as shown in FIG. 3D, the upper surfaces of the electrode pads 104 exposed in the through-via holes 110 are dry etched using, as a mask, the resist pattern (not shown) used in the step of FIG. 3C to form hollowed portions (anchors) 111 in the electrode pads 104. Thereafter, residue of the resist pattern is removed by ashing. Here, preferably, Cl-containing gas such as BCl₃ or the like is used as etching gas. The hollowed portion 111 preferably has a depth of 2 nm or more, more preferably 10 nm or more. Note that the term “depth” with respect to the hollowed portion 111 refers to a depth from the upper surface of the electrode pad 104 to a deepest portion of the hollowed portion 111.

Next, as shown in FIG. 3E, a barrier metal film 112 is deposited by, for example, sputtering to cover wall surfaces of the through-via holes 110 and the hollowed portions 111. Thereafter, a Cu seed layer (not shown) is formed on the barrier metal film 112 by, for example, sputtering, and then, a Cu film 113 is grown on the Cu seed layer by, for example, electroplating to fill the through-via holes 110 and the hollowed portions 111. Here, because the barrier metal film 112 is formed for the purpose of reducing or preventing diffusion of a material for the through-vias, specifically, Cu atoms, the barrier metal film 112 is preferably a conductive barrier film made of tungsten nitride (WN), tantalum nitride (TaN), titanium nitride (TiN), or the like. An insulating film may be formed to cover the wall surfaces of the through-via holes 110 before the formation of the barrier metal film 112 in order to electrically insulate the through-vias from the second silicon substrate 201.

Next, as shown in FIG. 3F, an excess of the Cu film 113 and the barrier metal film 112 extending off the through-via holes 110 is removed by polishing using, for example, CMP, leaving the Cu film 113 and the barrier metal film 112 only in the through-via holes 110 and the hollowed portions 111. By the aforementioned steps, through-vias 114 are formed which electrically connect the multilayer interconnects 203 of the second semiconductor chip 200 and the electrode pads 104 (i.e., the multilayer interconnects 103) of the first semiconductor chip 100.

As described above, in this embodiment, the semiconductor chips 100 and 200 are joined with the adhesive layer 150, and the multilayer interconnects 103 and 203 in the semiconductor chips 100 and 200 are electrically connected via the through-vias 114, resulting in a semiconductor device having a three-dimensional interconnection structure in which two semiconductor chips are stacked. Although, in this embodiment, a method for fabricating a semiconductor device in which the two semiconductor chips 100 and 200 are stacked has been described, needless to say a semiconductor device having a three-dimensional interconnection structure in which three or more semiconductor chips are stacked may be formed by repeating steps similar to those of FIGS. 3B-3F.

As described above, a feature of the semiconductor device fabricating method of the second embodiment is that a bottom portion of each through-via 114 is embedded in the hollowed portion 111 formed in the corresponding electrode pad 104 of the first semiconductor chip 100 so that the electrode pad 104 and the through-via 114 directly contact each other. As a result, advantageously, the electrode pad 104 and the through-via 114 contact each other without the formation of a bump. Moreover, the overall height of the semiconductor device can be advantageously reduced by an amount corresponding to the height of the bump. Moreover, because the bottom portion of the through-via 114 is embedded in the hollowed portion 111 of the electrode pad 104, the contact area between the through-via 114 and the electrode pad 104 can be increased, resulting in an increase in the bond strength between the through-via 114 and the electrode pad 104, and an increase in the mechanical strength against lateral force. Therefore, the mechanical strength of the semiconductor device having the three-dimensional interconnection structure can be increased.

In the second embodiment, the through-via 114 is formed after completion of fabrication of the second semiconductor chip 200. Alternatively, for example, the through-via 114 may be formed before or during formation of an interconnect layer on the second silicon substrate 201.

Moreover, in the second embodiment, if the formation of the through-via hole 110, the formation of the hollowed portion 111, and the formation of the through-via 114 by embedding the conductive film are continuously performed in vacuum, the through-via 114 and the electrode pad 104 can be joined while avoiding oxidation of the bottom surface of the through-via 114 and the upper surface of the electrode pad 104 of the first semiconductor chip 100, resulting in a greater bond strength between the through-via 114 and the electrode pad 104.

Moreover, in the second embodiment, the hollowed portion 111 preferably has a depth of 2 nm or more, more preferably 10 nm or more. Here, the term “depth” with respect to the hollowed portion 111 refers to a depth from the upper surface of the electrode pad 104 to a deepest portion of the hollowed portion 111. Specifically, if the depth of the hollowed portion 111 is 2 nm or more, a sufficient mechanical strength against lateral force can be maintained. If the depth of the hollowed portion 111 is 10 nm or more, a more sufficient mechanical strength against lateral force can be maintained. Here, the electrode pad 104 may have a thickness of, for example, about 1-5 μm. The electrode pad 104 may also have an area of, for example, but not limited to, about 100 μm×100 μm.

Moreover, in the second embodiment, the hollowed portion 111 preferably has a maximum diameter greater than a diameter of the through-via 114 at the upper surface of the electrode pad 104. In this case, the contact area between the through-via 114 and the electrode pad 104 can be further increased, resulting in a further increase in the reliability of the bond between the through-via 114 and the electrode pad 104. Specifically, instead of forming the hollowed portion 111 by dry etching in the step of FIG. 3D, as shown in FIG. 4 the hollowed portion 111 may be formed by wet etching using a Cl-containing etchant, such as FeCl₄ or the like, whereby the maximum diameter of the hollowed portion 111 can be caused to be greater than the diameter of the through-via 114 at the upper surface of the electrode pad 104. Here, the diameter of the through-via 114 (a diameter at the upper surface of the electrode pad 104) may be, for example, about 1-10 μm. Also, the through-via 114 may have a height of, for example, but not limited to, about 50 μm.

Moreover, in the second embodiment, the multilayer interconnect 103 (including the electrode pad 104), the multilayer interconnect 203 (including the electrode pad 204), and the through-via 114 may be made of, for example, but not limited to, copper or a copper alloy.

Moreover, in the second embodiment, as shown in, for example, FIG. 2, the electrode pad 104 is preferably formed so that the upper surface of the electrode pad 104 is lower than the upper surface of the first semiconductor chip 100 (i.e., an upper surface of the multilayer insulating film 102). In this case, the mechanical strength against lateral force can be further increased.

### Third Embodiment

A method for fabricating a semiconductor device according to a third embodiment of the present disclosure will be described hereinafter with reference to the drawings. FIGS. 5A-5G are cross-sectional views showing steps of the semiconductor device fabricating method of the third embodiment of the present disclosure.

Initially, as shown in FIG. 5A, in a manner similar to the step of FIG. 3A of the second embodiment, semiconductor elements (not shown) are formed in a first silicon substrate 101, and thereafter, although steps will not be described in detail, a multilayer insulating film 102 including one or more insulating films is formed on the first silicon substrate 101, and multilayer interconnects 103 each including a contact plug, an interconnect, a via, and the like are formed in the multilayer insulating film 102. Thereafter, electrode pads 104 are formed in an uppermost portion of the multilayer insulating film 102 so that the electrode pads 104 are connected to the multilayer interconnects 103. As a result, a first semiconductor chip 100 is formed which includes the first silicon substrate 101, the multilayer insulating film 102, the multilayer interconnects 103, the electrode pads 104, and the like. Similarly, semiconductor elements (not shown) are formed in a second silicon substrate 201, and thereafter, although steps will not be described in detail, a multilayer insulating film 202 including one or more insulating films is formed on the second silicon substrate 201, and multilayer interconnects 203 each including a contact plug, an interconnect, a via, and the like are formed in the multilayer insulating film 202. Thereafter, electrode pads 204 are formed in an uppermost portion of the multilayer insulating film 202 so that the electrode pads 204 are connected to the multilayer interconnects 203. As a result, a second semiconductor chip 200 is formed which includes the second silicon substrate 201, the multilayer insulating film 202, the multilayer interconnects 203, the electrode pads 204, and the like.

Here, of the multilayer insulating films 102 and 202, an insulating film in which interconnects are formed is preferably a carbon-containing silicon oxide film (SiOC film) for the purpose of reducing the capacitance between the interconnects.

Moreover, the interconnects, the vias, and the like constituting the multilayer interconnects 103 and 203 are preferably made of Cu (copper) or a Cu alloy for the purpose of reducing the resistance. The interconnects, the vias, and the like are preferably formed by a dual damascene process for the purpose of simplifying the process.

Moreover, although the electrode pads 104 and 204 may be made of Cu, aluminum (Al), an alloy thereof, or the like, the electrode pads 104 and 204 are preferably made of Cu for the purpose of reducing the resistance. The electrode pads 104 and 204 may have a two-dimensional shape of, for example, but not limited to, a circle (or substantially a circle), a square (or substantially a square), a rectangle (or substantially a rectangle), or the like.

Next, as shown in FIG. 5B, in a manner similar to the step of FIG. 3B of the second embodiment, the first and second semiconductor chips 100 and 200 are attached to each other with an adhesive layer 150 at a wafer level. Specifically, for example, a PBO resin having a thickness of about 15 μm is applied to an upper surface of the first semiconductor chip 100 to form the adhesive layer 150. Thereafter, the second semiconductor chip 200 is pressed against the first semiconductor chip 100 with the adhesive layer 150 being interposed therebetween. In this situation, for example, a thermal treatment is performed at 320° C. for 30 min to cure the adhesive layer 150. Note that the material for the adhesive layer 150 is not limited to the PBO resin, and may be a thermosetting adhesive, an ultraviolet curable adhesive, or the like.

Next, as shown in FIG. 5C, in a manner similar to that of FIG. 3C of the second embodiment, a resist pattern (not shown) having a through-via pattern is formed on the multilayer insulating film 202 of the second semiconductor chip 200 by photolithography. Thereafter, using the resist pattern as a mask, the multilayer insulating film 202, the second silicon substrate 201, and the adhesive layer 150 are successively dry etched to form through-via holes 110 penetrating the second silicon substrate 201. Thereafter, residue of the resist pattern is removed by ashing. As a result, upper surfaces of the electrode pads 104 of the first semiconductor chip 100 are exposed in the through-via holes 110. Note that, in this embodiment, in order to reliably establish electrical contact between through-vias and the multilayer interconnects 203 in the second semiconductor chip 200, large electrode pads 204 are formed in the step of FIG. 5A, and a portion of each of the electrode pads 204 is etched in the step of FIG. 5C to form the corresponding through-via hole 110 so that the through-via hole 110 contacts the electrode pad 204.

Next, as shown in FIG. 5D, a barrier metal film 112 is deposited to cover wall surfaces of the through-via holes 110 by, for example, sputtering. Here, because the barrier metal film 112 is formed for the purpose of reducing or preventing diffusion of a material for the through-vias, specifically, Cu atoms, the barrier metal film 112 is preferably a conductive barrier film made of tungsten nitride (WN), tantalum nitride (TaN), titanium nitride (TiN), or the like. An insulating film may be formed to cover the wall surfaces of the through-via holes 110 before the formation of the barrier metal film 112 in order to electrically insulate the through-vias from the second silicon substrate 201.

Next, as shown in FIG. 5E, bottom portions of the through-via holes 110, i.e., upper surfaces of the electrode pads 104 covered with the barrier metal film 112 are subjected to resputtering using, for example, Ar gas to form hollowed portions (anchors) 111 in the electrode pads 104. Here, the hollowed portion 111 preferably has a depth of 2 nm or more, more preferably 10 nm or more. Note that the term “depth” with respect to the hollowed portion 111 refers to a depth from the upper surface of the electrode pad 104 to a deepest portion of the hollowed portion 111.

Here, in the sputtering process of FIG. 5D, DC power is applied to a target so that a metal constituting the target is sputtered by, for example, Ar, whereby the metal is deposited on the substrate. By contrast, in the resputtering process of FIG. 5E, little DC power is applied to a target, and RF power is applied to a high-frequency coil to accelerate ionization of, for example, Ar, and also, bias power is applied to the substrate, whereby ionized Ar⁺ is attracted to the substrate to perform etching. Therefore, in the resputtering process of FIG. 5E, etching using Ar is predominant over deposition of the metal. Specific conditions for the sputtering process of FIG. 5D are, for example, that the target power is 20000 W, the substrate bias power is 230 W, the RF power is 0 W, and the Ar flow rate is 20 cm³/min (standard conditions). Specific conditions for the resputtering process of FIG. 5E are, for example, that the target power is 500 W, the substrate bias power is 400 W, the RF power is 1200 W, and the Ar flow rate is 15 cm³/min (standard conditions).

Next, as shown in FIG. 5F, a Cu seed layer (not shown) is formed on the barrier metal film 112 which covers wall surfaces of the through-via holes 110 and the hollowed portions 111 by, for example, sputtering. Thereafter, a Cu film 113 is grown on the Cu seed layer by, for example, electroplating to fill the through-via holes 110 and the hollowed portions 111.

Next, as shown in FIG. 5G, in a manner similar to the step of FIG. 3F of the second embodiment, an excess of the Cu film 113 and the barrier metal film 112 extending off the through-via holes 110 is removed by polishing using, for example, CMP, leaving the Cu film 113 and the barrier metal film 112 only in the through-via holes 110 and the hollowed portions 111. By the aforementioned steps, through-vias 114 are formed which electrically connect the multilayer interconnects 203 of the second semiconductor chip 200 and the electrode pads 104 (i.e., the multilayer interconnects 103) of the first semiconductor chip 100.

As described above, in this embodiment, the semiconductor chips 100 and 200 are joined with the adhesive layer 150, and the multilayer interconnects 103 and 203 in the semiconductor chips 100 and 200 are electrically connected via the through-vias 114, resulting in a semiconductor device having a three-dimensional interconnection structure in which two semiconductor chips are stacked. Although, in this embodiment, a method for fabricating a semiconductor device in which the two semiconductor chips 100 and 200 are stacked has been described, needless to say a semiconductor device having a three-dimensional interconnection structure in which three or more semiconductor chips are stacked may be formed by repeating steps similar to those of FIGS. 5B-5G.

As described above, a feature of the semiconductor device fabricating method of the third embodiment is that the bottom portions of each through-via 114 is embedded in the hollowed portion 111 formed in the corresponding electrode pad 104 of the first semiconductor chip 100 so that the electrode pad 104 and the through-via 114 directly contact each other. As a result, advantageously, the electrode pad 104 and the through-via 114 contact each other without the formation of a bump. Moreover, the overall height of the semiconductor device can be advantageously reduced by an amount corresponding to the height of the bump. Moreover, because the bottom portion of the through-via 114 is embedded in the hollowed portion 111 of the electrode pad 104, the contact area between the through-via 114 and the electrode pad 104 can be increased, resulting in an increase in the bond strength between the through-via 114 and the electrode pad 104, and an increase in the mechanical strength against lateral force. Therefore, the mechanical strength of the semiconductor device having the three-dimensional interconnection structure can be increased.

In the third embodiment, the through-via 114 is formed after completion of fabrication of the second semiconductor chip 200. Alternatively, for example, the through-via 114 may be formed before or during formation of an interconnect layer on the second silicon substrate 201.

Moreover, in the third embodiment, if the formation of the through-via hole 110, the formation of the barrier metal film 112, the formation of the hollowed portion 111, and the formation of the through-via 114 by embedding the conductive film are continuously performed in vacuum, the through-via 114 and the electrode pad 104 can be joined while avoiding oxidation of the bottom surface of the through-via 114 and the upper surface of the electrode pad 104 of the first semiconductor chip 100, resulting in a greater bond strength between the through-via 114 and the electrode pad 104.

Moreover, in the third embodiment, the hollowed portion 111 preferably has a depth of 2 nm or more, more preferably 10 nm or more. Here, the term “depth” with respect to the hollowed portion 111 refers to a depth from the upper surface of the electrode pad 104 to a deepest portion of the hollowed portion 111. Specifically, if the depth of the hollowed portion 111 is 2 nm or more, a sufficient mechanical strength against lateral force can be maintained. If the depth of the hollowed portion 111 is 10 nm or more, a more sufficient mechanical strength against lateral force can be maintained. Here, the electrode pad 104 may have a thickness of, for example, about 1-5 μm. The electrode pad 104 may also have an area of, for example, but not limited to, about 100 μm×100 μm.

Moreover, in the third embodiment, the hollowed portion 111 preferably has a maximum diameter greater than a diameter of the through-via 114 at the upper surface of the electrode pad 104. In this case, the contact area between the through-via 114 and the electrode pad 104 can be further increased, resulting in a further increase in the reliability of the bond between the through-via 114 and the electrode pad 104. Here, the diameter of the through-via 114 (a diameter at the upper surface of the electrode pad 104) may be, for example, about 1-10 μm. Also, the through-via 114 may have a height of, for example, but not limited to, about 50 μm.

Moreover, in the third embodiment, the multilayer interconnect 103 (including the electrode pad 104), the multilayer interconnect 203 (including the electrode pad 204), and the through-via 114 may be made of, for example, but not limited to, copper or a copper alloy.

Moreover, in the third embodiment, as shown in, for example, FIG. 2, the electrode pad 104 is preferably formed so that the upper surface of the electrode pad 104 is lower than the upper surface of the first semiconductor chip 100 (i.e., an upper surface of the multilayer insulating film 102). In this case, the mechanical strength against lateral force can be further increased.

### Fourth Embodiment

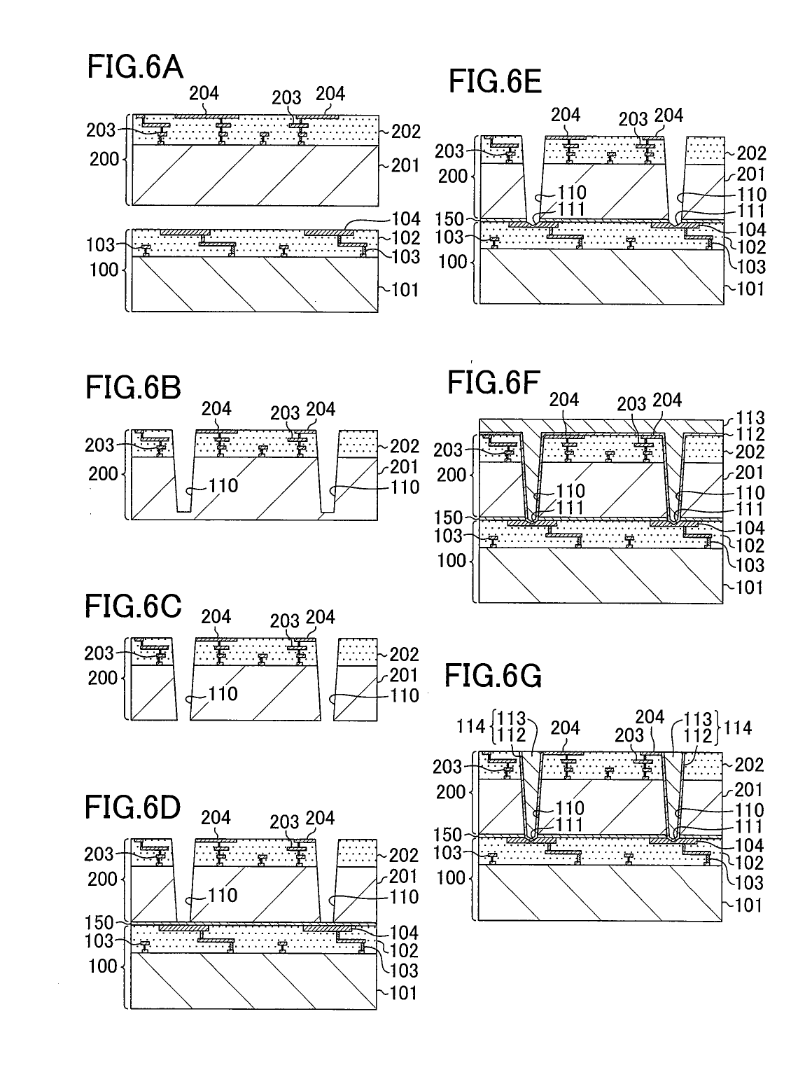

A method for fabricating a semiconductor device according to a fourth embodiment of the present disclosure will be described hereinafter with reference to the drawings. FIGS. 6A-6G are cross-sectional views showing steps of the semiconductor device fabricating method of the fourth embodiment of the present disclosure.

Initially, as shown in FIG. 6A, semiconductor elements (not shown) are formed in a first silicon substrate 101, and thereafter, although steps will not be described in detail, a multilayer insulating film 102 including one or more insulating films is formed on the first silicon substrate 101, and multilayer interconnects 103 each including a contact plug, an interconnect, a via, and the like are formed in the multilayer insulating film 102. Thereafter, electrode pads 104 are formed in an uppermost portion of the multilayer insulating film 102 so that the electrode pads 104 are connected to the multilayer interconnects 103. As a result, a first semiconductor chip 100 is formed which includes the first silicon substrate 101, the multilayer insulating film 102, the multilayer interconnects 103, the electrode pads 104, and the like. Similarly, semiconductor elements (not shown) are formed in a second silicon substrate 201, and thereafter, although steps will not be described in detail, a multilayer insulating film 202 including one or more insulating films is formed on the second silicon substrate 201, and multilayer interconnects 203 each including a contact plug, an interconnect, a via, and the like are formed in the multilayer insulating film 202. Thereafter, electrode pads 204 are formed in an uppermost portion of the multilayer insulating film 202 so that the electrode pads 204 are connected to the multilayer interconnects 203. As a result, a second semiconductor chip 200 is formed which includes the second silicon substrate 201, the multilayer insulating film 202, the multilayer interconnects 203, the electrode pads 204, and the like.

Here, of the multilayer insulating films 102 and 202, an insulating film in which interconnects are formed is preferably a carbon-containing silicon oxide film (SiOC film) for the purpose of reducing the capacitance between the interconnects.

Moreover, the interconnects, the vias, and the like constituting the multilayer interconnects 103 and 203 are preferably made of Cu (copper) or a Cu alloy for the purpose of reducing the resistance. The interconnects, the vias, and the like are preferably formed by a dual damascene process for the purpose of simplifying the process.

Moreover, although the electrode pads 104 and 204 may be made of Cu, aluminum (Al), an alloy thereof, or the like, the electrode pads 104 and 204 are preferably made of Cu for the purpose of reducing the resistance. The electrode pads 104 and 204 may have a two-dimensional shape of, for example, but not limited to, a circle (or substantially a circle), a square (or substantially a square), a rectangle (or substantially a rectangle), or the like.

Next, as shown in FIG. 6B, a resist pattern (not shown) having a through-via pattern is formed on the multilayer insulating film 202 of the second semiconductor chip 200 by photolithography. Thereafter, using the resist pattern as a mask, the multilayer insulating film 202 and the second silicon substrate 201 are successively dry etched to form through-via holes 110 reaching a lower portion of the second silicon substrate 201. Thereafter, residue of the resist pattern is removed by ashing. Note that, in this embodiment, in order to reliably establish electrical contact between through-vias and the multilayer interconnects 203 in the second semiconductor chip 200, large electrode pads 204 are formed in the step of FIG. 6A, and a portion of each of the electrode pads 204 is etched in the step of FIG. 6B to form the corresponding through-via hole 110 so that the through-via hole 110 contacts the electrode pad 204.

Next, as shown in FIG. 6C, bottom portions of the through-via holes 110 are exposed by polishing a lower surface of the second silicon substrate 201 by, for example, CMP. Here, wet etching may be performed instead of polishing.

Next, as shown in FIG. 6D, the first and second semiconductor chips 100 and 200 are attached to each other with an adhesive layer 150 at a wafer level. Specifically, for example, a PBO resin having a thickness of about 15 μm is applied to an upper surface of the first semiconductor chip 100 to form the adhesive layer 150. Thereafter, the second semiconductor chip 200 is pressed against the first semiconductor chip 100 with the adhesive layer 150 being interposed therebetween. In this situation, for example, a thermal treatment is performed at 320° C. for 30 min to cure the adhesive layer 150. Note that the material for the adhesive layer 150 is not limited to the PBO resin, and may be a thermosetting adhesive, an ultraviolet curable adhesive, or the like.

In this embodiment, in the step of FIG. 6D, the second semiconductor chip 200 having the through-via holes 110 which are not filled with a conductive material is attached to the first semiconductor chip 100. Therefore, the attachment process can be performed by utilizing optical observation of the through-via holes 110, whereby the chips can be easily aligned.

Next, as shown in FIG. 6E, the adhesive layer 150 is removed from the bottom portions of the through-via holes 110, and then, upper surfaces of the electrode pads 104 which are exposed in the through-via holes 110 are dry etched to form hollowed portions (anchors) 111 in the electrode pads 104. Here, preferably, Cl-containing gas such as BCl₃ or the like is used as etching gas. The hollowed portion 111 preferably has a depth of 2 nm or more, more preferably 10 nm or more. Note that the term “depth” with respect to the hollowed portion 111 refers to a depth from the upper surface of the electrode pad 104 to a deepest portion of the hollowed portion 111.

Next, as shown in FIG. 6F, a barrier metal film 112 is deposited by, for example, sputtering to cover wall surfaces of the through-via holes 110 and the hollowed portions 111. Thereafter, a Cu seed layer (not shown) is formed on the barrier metal film 112 by, for example, sputtering, and then, a Cu film 113 is grown on the Cu seed layer by, for example, electroplating to fill the through-via holes 110 and the hollowed portions 111. Here, because the barrier metal film 112 is formed for the purpose of reducing or preventing diffusion of a material for the through-vias, specifically, Cu atoms, the barrier metal film 112 is preferably a conductive barrier film made of tungsten nitride (WN), tantalum nitride (TaN), titanium nitride (TiN), or the like. An insulating film may be formed to cover the wall surfaces of the through-via holes 110 before the formation of the barrier metal film 112 in order to electrically insulate the through-vias from the second silicon substrate 201.

Next, FIG. 6G, an excess of the Cu film 113 and the barrier metal film 112 extending off the through-via holes 110 is removed by polishing using, for example, CMP, leaving the Cu film 113 and the barrier metal film 112 only in the through-via holes 110 and the hollowed portions 111. By the aforementioned steps, through-vias 114 are formed which electrically connect the multilayer interconnects 203 of the second semiconductor chip 200 and the electrode pads 104 (i.e., the multilayer interconnects 103) of the first semiconductor chip 100.

As described above, in this embodiment, the semiconductor chips 100 and 200 are joined with the adhesive layer 150, and the multilayer interconnects 103 and 203 in the semiconductor chips 100 and 200 are electrically connected via the through-vias 114, resulting in a semiconductor device having a three-dimensional interconnection structure in which two semiconductor chips are stacked. Although, in this embodiment, a method for fabricating a semiconductor device in which the two semiconductor chips 100 and 200 are stacked has been described, needless to say a semiconductor device having a three-dimensional interconnection structure in which three or more semiconductor chips are stacked may be formed by repeating steps similar to those of FIGS. 6B-6G.

As described above, a feature of the semiconductor device fabricating method of the fourth embodiment is that the bottom portion of the through-via 114 is embedded in the hollowed portion 111 formed in the electrode pad 104 of the first semiconductor chip 100 so that the electrode pad 104 and the through-via 114 directly contact each other. As a result, advantageously, the electrode pad 104 and the through-via 114 contact each other without the formation of a bump. Moreover, the overall height of the semiconductor device can be advantageously reduced by an amount corresponding to the height of the bump. Moreover, because the bottom portion of the through-via 114 is embedded in the hollowed portion 111 of the electrode pad 104, the contact area between the through-via 114 and the electrode pad 104 can be increased, resulting in an increase in the bond strength between the through-via 114 and the electrode pad 104, and an increase in the mechanical strength against lateral force. Therefore, the mechanical strength of the semiconductor device having the three-dimensional interconnection structure can be increased.

Moreover, in the fourth embodiment, when the first and second semiconductor chips 100 and 200 are attached to each other, the through-via holes 110 of the second semiconductor chip 200 are not yet filled with a conductive material. Therefore, the attachment process can be performed by utilizing optical observation of the through-via holes 110, whereby the chips can be easily aligned.

In the fourth embodiment, the through-via 114 is formed after completion of fabrication of the second semiconductor chip 200. Alternatively, for example, the through-via 114 may be formed before or during formation of an interconnect layer on the second silicon substrate 201.

Moreover, in the fourth embodiment, if the formation of the hollowed portion 111 and the formation of the through-via 114 by embedding the conductive film are continuously performed in vacuum, the through-via 114 and the electrode pad 104 can be joined while avoiding oxidation of the bottom surface of the through-via 114 and the upper surface of the electrode pad 104 of the first semiconductor chip 100, resulting in a greater bond strength between the through-via 114 and the electrode pad 104.

Moreover, in the fourth embodiment, the hollowed portion 111 preferably has a depth of 2 nm or more, more preferably 10 nm or more. Here, the term “depth” with respect to the hollowed portion 111 refers to a depth from the upper surface of the electrode pad 104 to a deepest portion of the hollowed portion 111. Specifically, if the depth of the hollowed portion 111 is 2 nm or more, a sufficient mechanical strength against lateral force can be maintained. If the depth of the hollowed portion 111 is 10 nm or more, a more sufficient mechanical strength against lateral force can be maintained. Here, the electrode pad 104 may have a thickness of, for example, about 1-5 μm. The electrode pad 104 may also have an area of, for example, but not limited to, about 100 μm×100 μm.

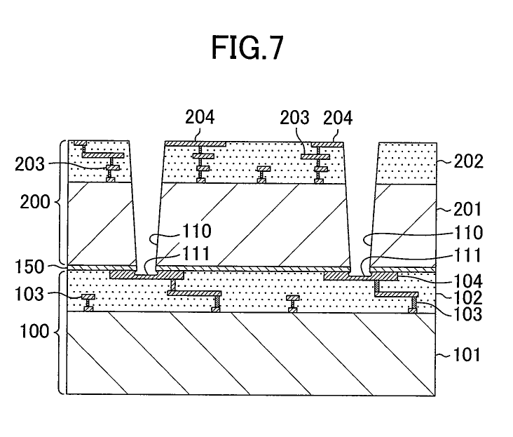

Moreover, in the fourth embodiment, the hollowed portion 111 preferably has a maximum diameter greater than a diameter of the through-via 114 at the upper surface of the electrode pad 104. In this case, the contact area between the through-via 114 and the electrode pad 104 can be further increased, resulting in a further increase in the reliability of the bond between the through-via 114 and the electrode pad 104. Specifically, instead of forming the hollowed portion 111 by dry etching in the step of FIG. 6E, as shown in FIG. 7 the hollowed portion 111 may be formed by wet etching using a Cl-containing etchant, such as FeCl₄ or the like, whereby the maximum diameter of the hollowed portion 111 can be caused to be greater than the diameter of the through-via 114 at the upper surface of the electrode pad 104. Here, the diameter of the through-via 114 (a diameter at the upper surface of the electrode pad 104) may be, for example, about 1-10 μm. Also, the through-via 114 may have a height of, for example, but not limited to, about 50 μm.

Moreover, in the fourth embodiment, the multilayer interconnect 103 (including the electrode pad 104), the multilayer interconnect 203 (including the electrode pad 204), and the through-via 114 may be made of, for example, but not limited to, copper or a copper alloy.

Moreover, in the fourth embodiment, as shown in, for example, FIG. 2, the electrode pad 104 is preferably formed so that the upper surface of the electrode pad 104 is lower than the upper surface of the first semiconductor chip 100 (i.e., an upper surface of the multilayer insulating film 102). In this case, the mechanical strength against lateral force can be further increased.

### Fifth Embodiment

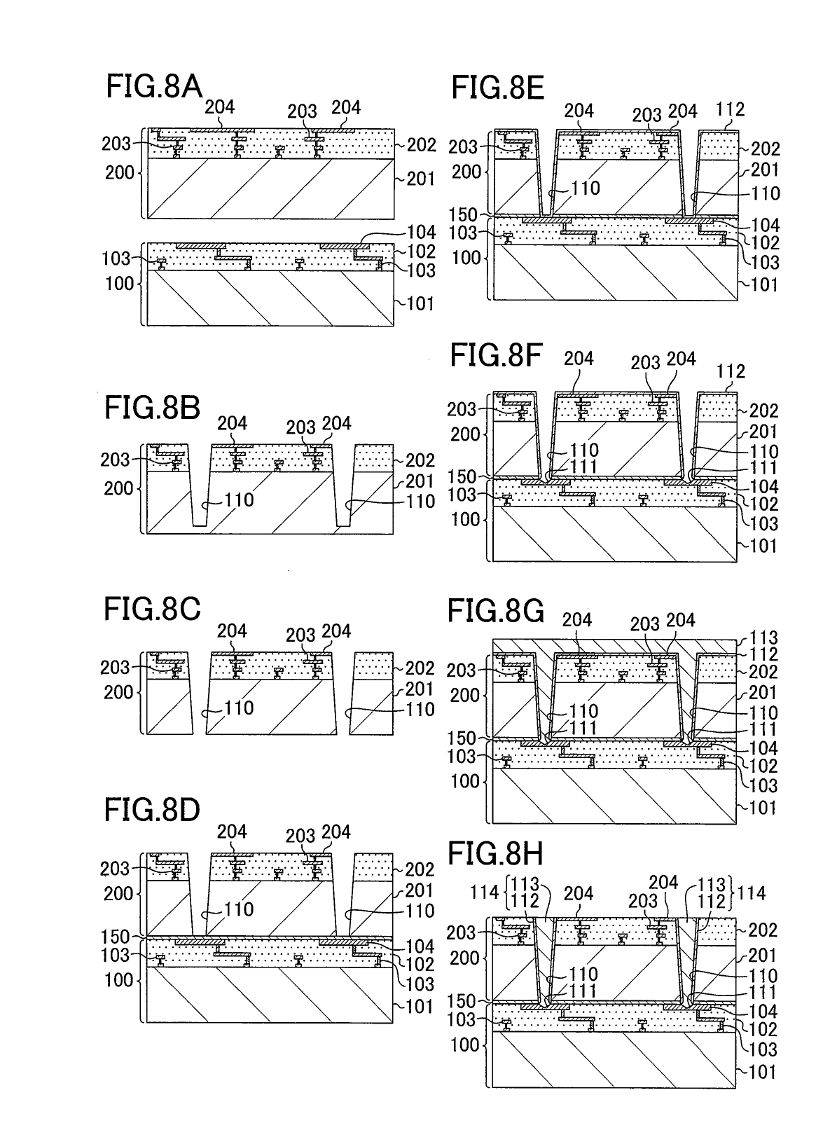

A method for fabricating a semiconductor device according to a fifth embodiment of the present disclosure will be described hereinafter with reference to the drawings. FIGS. 8A-8H are cross-sectional views showing steps of the semiconductor device fabricating method of the fifth embodiment of the present disclosure.

Initially, as shown in FIG. 8A, in a manner similar to the step of FIG. 6A of the fourth embodiment, semiconductor elements (not shown) are formed in a first silicon substrate 101, and thereafter, although steps will not be described in detail, a multilayer insulating film 102 including one or more insulating films is formed on the first silicon substrate 101, and multilayer interconnects 103 each including a contact plug, an interconnect, a via, and the like are formed in the multilayer insulating film 102. Thereafter, electrode pads 104 are formed in an uppermost portion of the multilayer insulating film 102 so that the electrode pads 104 are connected to the multilayer interconnects 103. As a result, a first semiconductor chip 100 is formed which includes the first silicon substrate 101, the multilayer insulating film 102, the multilayer interconnects 103, the electrode pads 104, and the like. Similarly, semiconductor elements (not shown) are formed in a second silicon substrate 201, and thereafter, although steps will not be described in detail, a multilayer insulating film 202 including one or more insulating films is formed on the second silicon substrate 201, and multilayer interconnects 203 each including a contact plug, an interconnect, a via, and the like are formed in the multilayer insulating film 202. Thereafter, electrode pads 204 are formed in an uppermost portion of the multilayer insulating film 202 so that the electrode pads 204 are connected to the multilayer interconnects 203. As a result, a second semiconductor chip 200 is formed which includes the second silicon substrate 201, the multilayer insulating film 202, the multilayer interconnects 203, the electrode pads 204, and the like.

Here, of the multilayer insulating films 102 and 202, an insulating film in which interconnects are formed is preferably a carbon-containing silicon oxide film (SiOC film) for the purpose of reducing the capacitance between the interconnects.

Moreover, the interconnects, the vias, and the like constituting the multilayer interconnects 103 and 203 are preferably made of Cu (copper) or a Cu alloy for the purpose of reducing the resistance. The interconnects, the vias, and the like are preferably formed by a dual damascene process for the purpose of simplifying the process.

Moreover, although the electrode pads 104 and 204 may be made of Cu, aluminum (Al), an alloy thereof, or the like, the electrode pads 104 and 204 are preferably made of Cu for the purpose of reducing the resistance. The electrode pads 104 and 204 may have a two-dimensional shape of, for example, but not limited to, a circle (or substantially a circle), a square (or substantially a square), a rectangle (or substantially a rectangle), or the like.

Next, as shown in FIG. 8B, in a manner similar to that of FIG. 6B of the fourth embodiment, a resist pattern (not shown) having a through-via pattern is formed on the multilayer insulating film 202 of the second semiconductor chip 200 by photolithography. Thereafter, using the resist pattern as a mask, the multilayer insulating film 202 and the second silicon substrate 201 are successively dry etched to form through-via holes 110 reaching a lower portion of the second silicon substrate 201. Thereafter, residue of the resist pattern is removed by ashing. Note that, in this embodiment, in order to reliably establish electrical contact between through-vias and the multilayer interconnects 203 in the second semiconductor chip 200, large electrode pads 204 are formed in the step of FIG. 8A, and a portion of each of the electrode pads 204 is etched in the step of FIG. 8B to form the corresponding through-via hole 110 so that the through-via hole 110 contacts the electrode pad 204.

Next, as shown in FIG. 8C, in a manner similar to the step of FIG. 6C of the fourth embodiment, bottom portions of the through-via holes 110 are exposed by polishing a lower surface of the second silicon substrate 201 by, for example, CMP. Here, wet etching may be performed instead of polishing.

Next, as shown in FIG. 8D, in a manner similar to the step of FIG. 6D of the fourth embodiment, the first and second semiconductor chips 100 and 200 are attached to each other with an adhesive layer 150 at a wafer level. Specifically, for example, a PBO resin having a thickness of about 15 μm is applied to an upper surface of the first semiconductor chip 100 to form the adhesive layer 150. Thereafter, the second semiconductor chip 200 is pressed against the first semiconductor chip 100 with the adhesive layer 150 being interposed therebetween. In this situation, for example, a thermal treatment is performed at 320° C. for 30 min to cure the adhesive layer 150. Note that the material for the adhesive layer 150 is not limited to the PBO resin, and may be a thermosetting adhesive, an ultraviolet curable adhesive, or the like.

In this embodiment, in the step of FIG. 8D, the second semiconductor chip 200 having the through-via holes 110 which are not filled with a conductive material is attached to the first semiconductor chip 100. Therefore, the attachment process can be performed by utilizing optical observation of the through-via holes 110, whereby the chips can be easily aligned.

Next, as shown in FIG. 8E, the adhesive layer 150 is removed from the bottom portions of the through-via holes 110, and then, a barrier metal film 112 is deposited by, for example, sputtering to cover wall surfaces of the through-via holes 110. Here, because the barrier metal film 112 is formed for the purpose of reducing or preventing diffusion of a material for the through-vias, specifically, Cu atoms, the barrier metal film 112 is preferably a conductive barrier film made of tungsten nitride (WN), tantalum nitride (TaN), titanium nitride (TiN), or the like. An insulating film may be formed to cover the wall surfaces of the through-via holes 110 before the formation of the barrier metal film 112 in order to electrically insulate the through-vias from the second silicon substrate 201.

Next, as shown in FIG. 8F, bottom portions of the through-via holes 110, i.e., upper surfaces of the electrode pads 104 covered with the barrier metal film 112 are subjected to resputtering using, for example, Ar gas to form hollowed portions (anchors) 111 in the electrode pads 104. Here, the hollowed portion 111 preferably has a depth of 2 nm or more, more preferably 10 nm or more. Note that the term “depth” with respect to the hollowed portion 111 refers to a depth from the upper surface of the electrode pad 104 to a deepest portion of the hollowed portion 111.

Here, in the sputtering process of FIG. 8E, DC power is applied to a target so that a metal constituting the target is sputtered by, for example, Ar, whereby the metal is deposited on the substrate. By contrast, in the resputtering process of FIG. 8F, little DC power is applied to a target, and RF power is applied to a high-frequency coil to accelerate ionization of, for example, Ar, and also, bias power is applied to the substrate, whereby ionized Ar⁺ is attracted to the substrate to perform etching. Therefore, in the resputtering process of FIG. 8F, etching using Ar is predominant over deposition of the metal. Specific conditions for the sputtering process of FIG. 8E are, for example, that the target power is 20000 W, the substrate bias power is 230 W, the RF power is 0 W, and the Ar flow rate is 20 cm³/min (standard conditions). Specific conditions for the resputtering process of FIG. 8F are, for example, that the target power is 500 W, the substrate bias power is 400 W, the RF power is 1200 W, and the Ar flow rate is 15 cm³/min (standard conditions).

Next, as shown in FIG. 8G, a Cu seed layer (not shown) is formed on the barrier metal film 112 which covers wall surfaces of the through-via holes 110 and the hollowed portions 111 by, for example, sputtering. Thereafter, a Cu film 113 is grown on the Cu seed layer by, for example, electroplating to fill the through-via holes 110 and the hollowed portions 111.

Next, as shown in FIG. 8H, in a manner similar to the step of FIG. 6G of the fourth embodiment, an excess of the Cu film 113 and the barrier metal film 112 extending off the through-via holes 110 is removed by polishing using, for example, CMP, leaving the Cu film 113 and the barrier metal film 112 only in the through-via holes 110 and the hollowed portions 111. By the aforementioned steps, through-vias 114 are formed which electrically connect the multilayer interconnects 203 of the second semiconductor chip 200 and the electrode pads 104 (i.e., the multilayer interconnects 103) of the first semiconductor chip 100.

As described above, in this embodiment, the semiconductor chips 100 and 200 are joined with the adhesive layer 150, and the multilayer interconnects 103 and 203 in the semiconductor chips 100 and 200 are electrically connected via the through-vias 114, resulting in a semiconductor device having a three-dimensional interconnection structure in which two semiconductor chips are stacked. Although, in this embodiment, a method for fabricating a semiconductor device in which the two semiconductor chips 100 and 200 are stacked has been described, needless to say a semiconductor device having a three-dimensional interconnection structure in which three or more semiconductor chips are stacked may be formed by repeating steps similar to those of FIGS. 8B-8H.

As described above, a feature of the semiconductor device fabricating method of the fifth embodiment is that the bottom portion of the through-via 114 is embedded in the hollowed portion 111 formed in the electrode pad 104 of the first semiconductor chip 100 so that the electrode pad 104 and the through-via 114 directly contact each other. As a result, advantageously, the electrode pad 104 and the through-via 114 contact each other without the formation of a bump. Moreover, the overall height of the semiconductor device can be advantageously reduced by an amount corresponding to the height of the bump. Moreover, because the bottom portion of the through-via 114 is embedded in the hollowed portion 111 of the electrode pad 104, the contact area between the through-via 114 and the electrode pad 104 can be increased, resulting in an increase in the bond strength between the through-via 114 and the electrode pad 104, and an increase in the mechanical strength against lateral force. Therefore, the mechanical strength of the semiconductor device having the three-dimensional interconnection structure can be increased.

Moreover, in the fifth embodiment, when the first and second semiconductor chips 100 and 200 are attached to each other, the through-via holes 110 of the second semiconductor chip 200 are not yet filled with a conductive material. Therefore, the attachment process can be performed by utilizing optical observation of the through-via holes 110, whereby the chips can be easily aligned.

In the fifth embodiment, the through-via 114 is formed after completion of fabrication of the second semiconductor chip 200. Alternatively, for example, the through-via 114 may be formed before or during formation of an interconnect layer on the second silicon substrate 201.

Moreover, in the fifth embodiment, if the formation of the barrier metal film 112, the formation of the hollowed portion 111, and the formation of the through-via 114 by embedding the conductive film are continuously performed in vacuum, the through-via 114 and the electrode pad 104 can be joined while avoiding oxidation of the bottom surface of the through-via 114 and the upper surface of the electrode pad 104 of the first semiconductor chip 100, resulting in a greater bond strength between the through-via 114 and the electrode pad 104.

Moreover, in the fifth embodiment, the hollowed portion 111 preferably has a depth of 2 nm or more, more preferably 10 nm or more. Here, the term “depth” with respect to the hollowed portion 111 refers to a depth from the upper surface of the electrode pad 104 to a deepest portion of the hollowed portion 111. Specifically, if the depth of the hollowed portion 111 is 2 nm or more, a sufficient mechanical strength against lateral force can be maintained. If the depth of the hollowed portion 111 is 10 nm or more, a more sufficient mechanical strength against lateral force can be maintained. Here, the electrode pad 104 may have a thickness of, for example, about 1-5 μm. The electrode pad 104 may also have an area of, for example, but not limited to, about 100 μm×100 μm.

Moreover, in the fifth embodiment, the hollowed portion 111 preferably has a maximum diameter greater than a diameter of the through-via 114 at the upper surface of the electrode pad 104. In this case, the contact area between the through-via 114 and the electrode pad 104 can be further increased, resulting in a further increase in the reliability of the bond between the through-via 114 and the electrode pad 104. Here, the diameter of the through-via 114 (a diameter at the upper surface of the electrode pad 104) may be, for example, about 1-10 μm. Also, the through-via 114 may have a height of, for example, but not limited to, about 50 μm.

Moreover, in the fifth embodiment, the multilayer interconnect 103 (including the electrode pad 104), the multilayer interconnect 203 (including the electrode pad 204), and the through-via 114 may be made of, for example, but not limited to, copper or a copper alloy.

Moreover, in the fifth embodiment, as shown in, for example, FIG. 2, the electrode pad 104 is preferably formed so that the upper surface of the electrode pad 104 is lower than the upper surface of the first semiconductor chip 100 (i.e., an upper surface of the multilayer insulating film 102). In this case, the mechanical strength against lateral force can be further increased.

### Sixth Embodiment

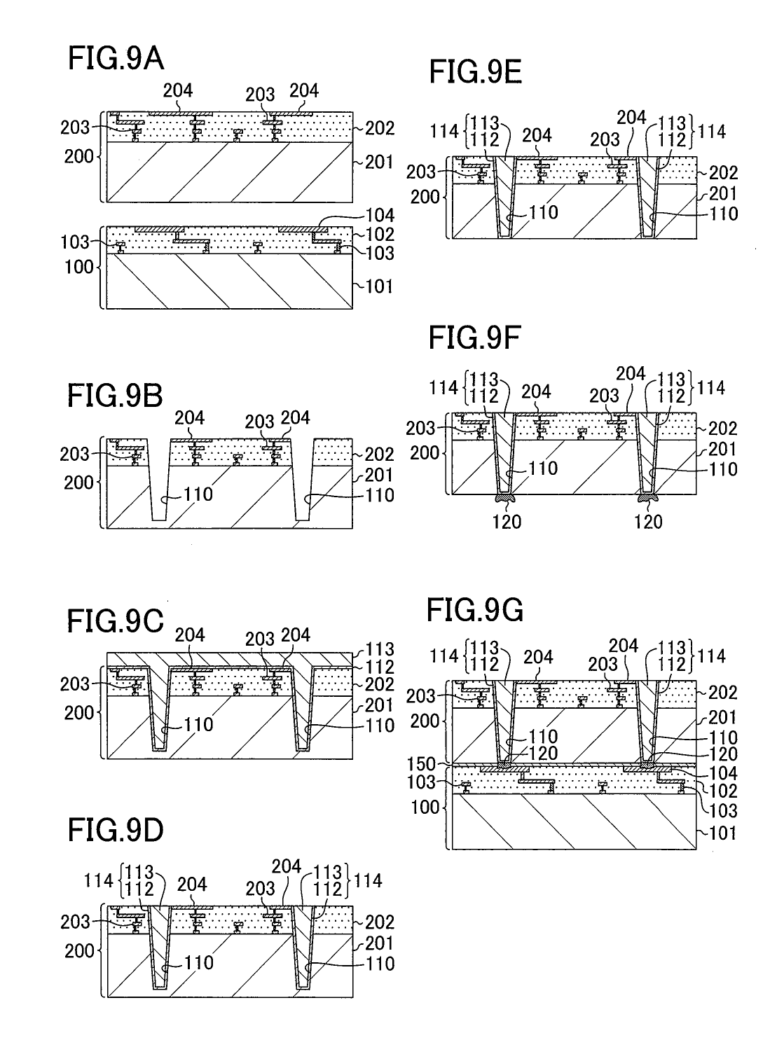

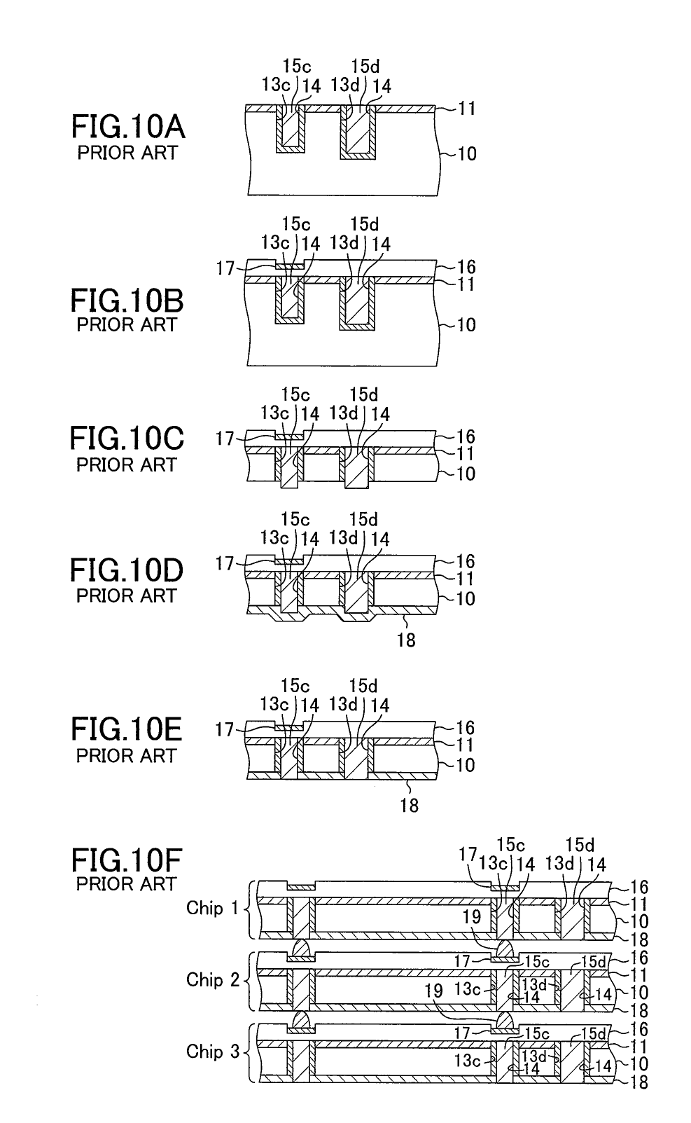

A method for fabricating a semiconductor device according to a sixth embodiment of the present disclosure will be described hereinafter with reference to the drawings. FIGS. 9A-9G are cross-sectional views showing steps of the semiconductor device fabricating method of the sixth embodiment of the present disclosure.

Initially, as shown in FIG. 9A, semiconductor elements (not shown) are formed in a first silicon substrate 101, and thereafter, although steps will not be described in detail, a multilayer insulating film 102 including one or more insulating films is formed on the first silicon substrate 101, and multilayer interconnects 103 each including a contact plug, an interconnect, a via, and the like are formed in the multilayer insulating film 102. Thereafter, electrode pads 104 are formed in an uppermost portion of the multilayer insulating film 102 so that the electrode pads 104 are connected to the multilayer interconnects 103. As a result, a first semiconductor chip 100 is formed which includes the first silicon substrate 101, the multilayer insulating film 102, the multilayer interconnects 103, the electrode pads 104, and the like. Similarly, semiconductor elements (not shown) are formed in a second silicon substrate 201, and thereafter, although steps will not be described in detail, a multilayer insulating film 202 including one or more insulating films is formed on the second silicon substrate 201, and multilayer interconnects 203 each including a contact plug, an interconnect, a via, and the like are formed in the multilayer insulating film 202. Thereafter, electrode pads 204 are formed in an uppermost portion of the multilayer insulating film 202 so that the electrode pads 204 are connected to the multilayer interconnects 203. As a result, a second semiconductor chip 200 is formed which includes the second silicon substrate 201, the multilayer insulating film 202, the multilayer interconnects 203, the electrode pads 204, and the like.

Here, of the multilayer insulating films 102 and 202, an insulating film in which interconnects are formed is preferably a carbon-containing silicon oxide film (SiOC film) for the purpose of reducing the capacitance between the interconnects.

Moreover, the interconnects, the vias, and the like constituting the multilayer interconnects 103 and 203 are preferably made of Cu (copper) or a Cu alloy for the purpose of reducing the resistance. The interconnects, the vias, and the like are preferably formed by a dual damascene process for the purpose of simplifying the process.

Moreover, although the electrode pads 104 and 204 may be made of Cu, aluminum (Al), an alloy thereof, or the like, the electrode pads 104 and 204 are preferably made of Cu for the purpose of reducing the resistance. The electrode pads 104 and 204 may have a two-dimensional shape of, for example, but not limited to, a circle (or substantially a circle), a square (or substantially a square), a rectangle (or substantially a rectangle), or the like.

Next, as shown in FIG. 9B, a resist pattern (not shown) having a through-via pattern is formed on the multilayer insulating film 202 of the second semiconductor chip 200 by photolithography. Thereafter, using the resist pattern as a mask, the multilayer insulating film 202 and the second silicon substrate 201 are successively dry etched to form through-via holes 110 reaching a lower portion of the second silicon substrate 201. Thereafter, residue of the resist pattern is removed by ashing. Note that, in this embodiment, in order to reliably establish electrical contact between through-vias and the multilayer interconnects 203 in the second semiconductor chip 200, large electrode pads 204 are formed in the step of FIG. 9A, and a portion of each of the electrode pads 204 is etched in the step of FIG. 9B to form the corresponding through-via hole 110 so that the through-via hole 110 contacts the electrode pad 204.

Next, as shown in FIG. 9C, a barrier metal film 112 is deposited by, for example, sputtering to cover wall surfaces of the through-via holes 110. Thereafter, a Cu seed layer (not shown) is formed on the barrier metal film 112 by, for example, sputtering, and then, a Cu film 113 is grown on the Cu seed layer by, for example, electroplating to fill the through-via holes 110. Here, because the barrier metal film 112 is formed for the purpose of reducing or preventing diffusion of a material for the through-vias, specifically, Cu atoms, the barrier metal film 112 is preferably a conductive barrier film made of tungsten nitride (WN), tantalum nitride (TaN), titanium nitride (TiN), or the like. An insulating film may be formed to cover the wall surfaces of the through-via holes 110 before the formation of the barrier metal film 112 in order to electrically insulate the through-vias from the second silicon substrate 201.

Next, as shown in FIG. 9D, an excess of the Cu film 113 and the barrier metal film 112 extending off the through-via holes 110 is removed by polishing using, for example, CMP, leaving the Cu film 113 and the barrier metal film 112 only in the through-via holes 110. By the aforementioned steps, through-vias 114 are formed which electrically connect to the multilayer interconnects 203 of the second semiconductor chip 200.

Next, as shown in FIG. 9E, bottom portions of the through-via holes 110 are exposed by polishing a lower surface of the second silicon substrate 201 by, for example, CMP. Here, wet etching may be performed instead of polishing.

Next, as shown in FIG. 9F, a metal-containing film 120 is selectively deposited on the bottom portions of the through-vias 114 by, for example, electroless plating. The metal-containing film 120 may be made of, for example, Cu, Ni, Co, or the like, which can be formed by electroless plating, preferably Cu for the purpose of reducing the resistance.

Next, as shown in FIG. 9G, the first and second semiconductor chips 100 and 200 are attached to each other with an adhesive layer 150 at a wafer level. The metal-containing film 120 formed on the bottom portions of the through-vias 114, and the electrode pads 104 of the first semiconductor chip 100 are joined by, for example, thermo-compression. Specifically, for example, a PBO resin having a thickness of about 15 μm is applied to an upper surface of the first semiconductor chip 100 (excluding regions where the electrode pads 104 are formed) to form the adhesive layer 150. Thereafter, the second semiconductor chip 200 is pressed against the first semiconductor chip 100 with the adhesive layer 150 being interposed therebetween. In this situation, for example, a thermal treatment is performed at 320° C. for 30 min to cure the adhesive layer 150. Note that the material for the adhesive layer 150 is not limited to the PBO resin, and may be a thermosetting adhesive, an ultraviolet curable adhesive, or the like.

As described above, in this embodiment, the semiconductor chips 100 and 200 are joined with the adhesive layer 150, and the multilayer interconnects 103 and 203 in the semiconductor chips 100 and 200 are electrically connected via the through-vias 114, resulting in a semiconductor device having a three-dimensional interconnection structure in which two semiconductor chips are stacked. Although, in this embodiment, a method for fabricating a semiconductor device in which the two semiconductor chips 100 and 200 are stacked has been described, needless to say a semiconductor device having a three-dimensional interconnection structure in which three or more semiconductor chips are stacked may be formed by repeating steps similar to those of FIGS. 9B-9G.

According to the sixth embodiment, the metal-containing film 120 is formed on the bottom portions of the through-vias 114, and the metal-containing film 120 and the electrode pads 104 contact each other. Therefore, uneven interfaces can be formed between the through-via 114 and the metal-containing film 120, and between the metal-containing film 120 and the electrode pad 104. Therefore, the effective contact area between the through-via 114 and the electrode pad 104 can be increased, resulting in an increase in the bond strength between the through-via 114 and the electrode pad 104.

In the sixth embodiment, the through-via 114 is formed after completion of fabrication of the second semiconductor chip 200. Alternatively, for example, the through-via 114 may be formed before or during formation of an interconnect layer on the second silicon substrate 201.

Moreover, in the sixth embodiment, the multilayer interconnect 103 (including the electrode pad 104), the multilayer interconnect 203 (including the electrode pad 204), and the through-via 114 may be made of, for example, but not limited to, copper or a copper alloy.

Moreover, in the sixth embodiment, as shown in, for example, FIG. 2, the electrode pad 104 is preferably formed so that the upper surface of the electrode pad 104 is lower than the upper surface of the first semiconductor chip 100 (i.e., an upper surface of the multilayer insulating film 102). In this case, the mechanical strength against lateral force can be further increased.

What is claimed is:

1. A semiconductor device comprising:
a first semiconductor chip;
an electrode pad formed in an upper surface portion of the first semiconductor chip;
a second semiconductor chip formed on the first semiconductor chip; and
a through-via formed in the second semiconductor chip,
wherein
a hollowed portion is formed in the electrode pad, and a bottom portion of the through-via is embedded in the hollowed portion.

2. The semiconductor device of claim 1, wherein
the hollowed portion has a depth of 2 nm or more.

3. The semiconductor device of claim 1, wherein
the hollowed portion has a depth of 10 nm or more.

4. The semiconductor device of claim 1, wherein
a maximum diameter of the hollowed portion is greater than a diameter of the through-via at an upper surface of the electrode pad.

5. The semiconductor device of claim 1, wherein
an upper surface of the electrode pad is lower than an upper surface of the first semiconductor chip.

6. The semiconductor device of claim 1, wherein
the electrode pad and the through-via directly contact each other without a bump interposed therebetween.

7. The semiconductor device of claim 1, wherein
an adhesive layer is formed between the first and second semiconductor chips.

8. The semiconductor device of claim 1, wherein
the through-via is electrically connected to an interconnect formed in the second semiconductor chip.

9. The semiconductor device of claim 1, wherein
the electrode pad is made of a material containing copper.

10. A method for fabricating a semiconductor device, comprising the steps of:
(a) preparing a first semiconductor chip including an electrode pad in an upper surface portion thereof, and a second semiconductor chip;
(b) attaching the second semiconductor chip to an upper surface of the first semiconductor chip;
(c) forming a through-via hole in the second semiconductor chip;
(d) after steps (b) and (c), forming a hollowed portion in the electrode pad; and
(e) forming a through-via by embedding a conductive film in the through-via hole and the hollowed portion.

11. The method of claim 10, wherein
step (c) is performed after step (b).

12. The method of claim 11, wherein
step (d) includes forming the hollowed portion by dry etching or wet etching.

13. The method of claim 12, further comprising the step of:
between steps (d) and (e), forming a barrier metal film on a wall surface of each of the through-via hole and the hollowed portion.

14. The method of claim 11, wherein
step (d) includes forming a barrier metal film on a wall surface of the through-via hole and then forming the hollowed portion in the electrode pad by resputtering.

15. The method of claim 14, wherein
the resputtering is performed using Ar gas.

16. The method of claim 10, wherein
step (c) is performed before step (b).

17. The method of claim 16, wherein
step (c) includes forming the through-via hole extending to a mid-depth of the second semiconductor chip and then polishing or etching a surface of the second semiconductor chip which the through-via hole does not penetrate, until a bottom surface of the through-via hole is exposed.

18. The method of claim 16, wherein
step (d) includes forming the hollowed portion by dry etching or wet etching.

19. The method of claim 18, further comprising the step of:
between steps (d) and (e), forming a barrier metal film on a wall surface of each of the through-via hole and the hollowed portion.

20. The method of claim 16, wherein
step (d) includes forming a barrier metal film on a wall surface of the through-via hole and then forming the hollowed portion in the electrode pad by resputtering.

21. The method of claim 20, wherein
the resputtering is performed using Ar gas.

22. The method of claim 10, wherein
the hollowed portion has a depth of 2 nm or more.

23. The method of claim 10, wherein
the hollowed portion has a depth of 10 nm or more.

24. The method of claim 10, wherein
a maximum diameter of the hollowed portion is greater than a diameter of the through-via at an upper surface of the electrode pad.

25. The method of claim 10, wherein
an upper surface of the electrode pad is lower than the upper surface of the first semiconductor chip.

26. The method of claim 10, wherein
the through-via is electrically connected to an interconnect formed in the second semiconductor chip.

27. A method for fabricating a semiconductor device, comprising the steps of:
(a) preparing a first semiconductor chip including an electrode pad in an upper surface portion thereof, and a second semiconductor chip;
(b) forming a through-via in the second semiconductor chip;
(c) forming a metal-containing film in a bottom portion of the through-via; and
(d) attaching the second semiconductor chip to an upper surface of the first semiconductor chip, and causing the metal-containing film formed in the bottom portion of the through-via to contact the electrode pad.

28. The method of claim 27, wherein
step (b) includes forming a through-via hole extending to a mid-depth of the second semiconductor chip, the through-via hole corresponding to the through-via, then embedding a conductive film in the through-via hole to form the through-via, and then polishing or etching a surface of the second semiconductor chip which the through-via does not penetrate, until a bottom surface of the through-via is exposed.

29. The method of claim 27, wherein
step (c) includes forming the metal-containing film by electroless plating.

30. The method of claim 27, wherein
the metal-containing film contains Cu, Ni, or Co.

31. The method of claim 10, wherein
the electrode pad is made of a material containing copper.

32. The method of claim 27, wherein
the electrode pad is made of a material containing copper.
